(19) United States
(12) Patent Application Publication
(10) Pub. No.: US 2009/0218644 A1
(43) Pub. Date: Sep. 3, 2009

(54) Integrated Circuit, Memory Device, and Method of Manufacturing an Integrated Circuit

(76) Inventor: Gill Yong Lee, Dresden (DE)

Correspondence Address: SLATER & MATSIL, L.L.P., 17950 PRESTON ROAD, SUITE 1000, DALLAS, TX, 75252, US

(21) Appl. No.: 12/040,035

(22) Filed: Feb. 29, 2008

(51) Int. Cl. H01L 29/82; H01L 23/52; H01L 21/822

(52) U.S. Cl. 257/421; 438/3; 257/751; 257/E21.606; 257/E29.323; 257/E23.141

(57) ABSTRACT

According to one embodiment of the present invention, an integrated circuit including a plurality of conductive lines is provided. The conductive lines are configured to guide electric currents or voltages. The conductive lines are at least partially surrounded by material which increases the electric field confinement of electric fields occurring within the conductive lines, and which functions as a diffusion barrier for material included within the conductive lines.

### TECHNICAL FIELD

In various embodiments, the present invention relates to an integrated circuit, a memory device and a method of manufacturing an integrated circuit.

### BACKGROUND

Integrated circuits having resistivity changing memory cells are known. The resistivity changing memory cells may, for example, be magneto-resistive memory cells involving spin electronics, which combines semiconductor technology and magnetics. The spin of an electron, rather than the charge, is used to indicate the presence of a “1” or “0”. One such spin electronic device is a magnetic random-access memory (MRAM), which includes conductive lines positioned perpendicular to one another in different metal layers, the conductive lines sandwiching a magnetic stack. The place where the conductive lines intersect is called a cross-point. A current flowing through one of the conductive lines generates a magnetic field around the conductive line and orients the magnetic polarity into a certain direction along the wire or conductive line. A current flowing through the other conductive line induces the magnetic field and can also partially turn the magnetic polarity. Digital information, represented as a “0” or “1” is stored in the alignment of magnetic moments. The resistance oft the magnetic component depends on the moment's alignment. The stored state is read from the element by detecting the component's resistive state. A memory cell may be constructed by placing the conductive lines and cross-points in a matrix structure or array having rows and columns.

FIG. 6 illustrates a perspective view of a MRAM device 610 having bit lines 612 located orthogonal to word lines 614 in adjacent metallization layers. Magnetic stacks 616 are positioned between the bit lines 612 and word lines 614 adjacent and electrically coupled to bit lines 612 and word lines 614. Magnetic stacks 616 preferably include multiple layers, including a soft layer 618, a tunnel layer 620, and a hard layer 622, for example. Soft layer 618 and hard layer 622 preferably include a plurality of magnetic metal layers, for example, eight to twelve layers of materials such as PtMn, CoFe, Ru, and NiFe, as examples. A logic state is storable in the soft layer 618 of the magnetic stacks 616 located at the junction of the bitlines 612 and word lines 614 by running a current in the appropriate direction within the bit lines 612 and word lines 614 which changes the resistance of the magnetic stacks 616.

In order to read the logic state stored in the soft layer 618 of the magnetic stack 616, a schematic such as the one shown in FIG. 7, including a sense amplifier (SA) 730, may be used to determine the logic state stored in an unknown memory cell MCu. A reference voltage UR is applied to one end of the unknown memory cell MCu. The other end of the unknown memory cell MCu is coupled to a measurement resistor Rₘ₁. The other end of the measurement resistor Rₘ₁ is coupled to ground. The current running through the unknown memory cell MCu is equal to current I_{cell}. A reference circuit 732 supplies a reference current I_{ref} that is run into measurement resistor Rₘ₂. The other end of the measurement resistor Rₘ₂ is coupled to ground, as shown.

It is desirable to improve the reliability of integrated circuits having resistivity changing memory cells.

### BRIEF DESCRIPTION OF THE DRAWINGS

In the drawings, like reference characters generally refer to the same parts throughout the different views. The drawings are not necessarily to scale, emphasis instead generally being placed upon illustrating the principles of the invention. In the following description, various embodiments of the invention are described with reference to the following drawings, in which:

FIG. 1 shows a cross-sectional view of an integrated circuit according to one embodiment of the present invention;

FIG. 2 shows a flow chart of a method of manufacturing an integrated circuit according to one embodiment of the present invention;

FIG. 3A shows a cross-sectional view of a processing stage of manufacturing an integrated circuit according to one embodiment of the present invention;

FIG. 3B shows a cross-sectional view of a processing stage of manufacturing an integrated circuit according to one embodiment of the present invention;

FIG. 3C shows a cross-sectional view of a processing stage of manufacturing an integrated circuit according to one embodiment of the present invention;

FIG. 3D shows a cross-sectional view of a processing stage of manufacturing an integrated circuit according to one embodiment of the present invention;

FIG. 3E shows a cross-sectional view of a processing stage of manufacturing an integrated circuit according to one embodiment of the present invention;

FIG. 3F shows a cross-sectional view of a processing stage of manufacturing an integrated circuit according to one embodiment of the present invention;

FIG. 3G shows a cross-sectional view of a processing stage of manufacturing an integrated circuit according to one embodiment of the present invention;

FIG. 3H shows a cross-sectional view of a processing stage of manufacturing an integrated circuit according to one embodiment of the present invention;

FIG. 3I shows a cross-sectional view of a processing stage of manufacturing an integrated circuit according to one embodiment of the present invention;

FIG. 3J shows a cross-sectional view of a processing stage of manufacturing an integrated circuit according to one embodiment of the present invention;

FIG. 3K shows a cross-sectional view of a processing stage of manufacturing an integrated circuit according to one embodiment of the present invention;

FIG. 3L shows a cross-sectional view of a processing stage of manufacturing an integrated circuit according to one embodiment of the present invention;

FIG. 4A shows a cross-sectional view of an integrated circuit;

FIG. 4B shows a cross-sectional view of an integrated circuit according to one embodiment of the present invention;

FIG. 5A shows a cross-sectional view of a memory module according to one embodiment of the present invention;

FIG. 5B shows a cross-sectional view of a memory module according to one embodiment of the present invention;

FIG. 6 shows a schematic perspective view of an integrated circuit having magneto-resistive memory cells; and

FIG. 7 shows a circuit usable in conjunction with the integrated circuit shown in FIG. 6.

### DETAILED DESCRIPTION OF ILLUSTRATIVE EMBODIMENTS

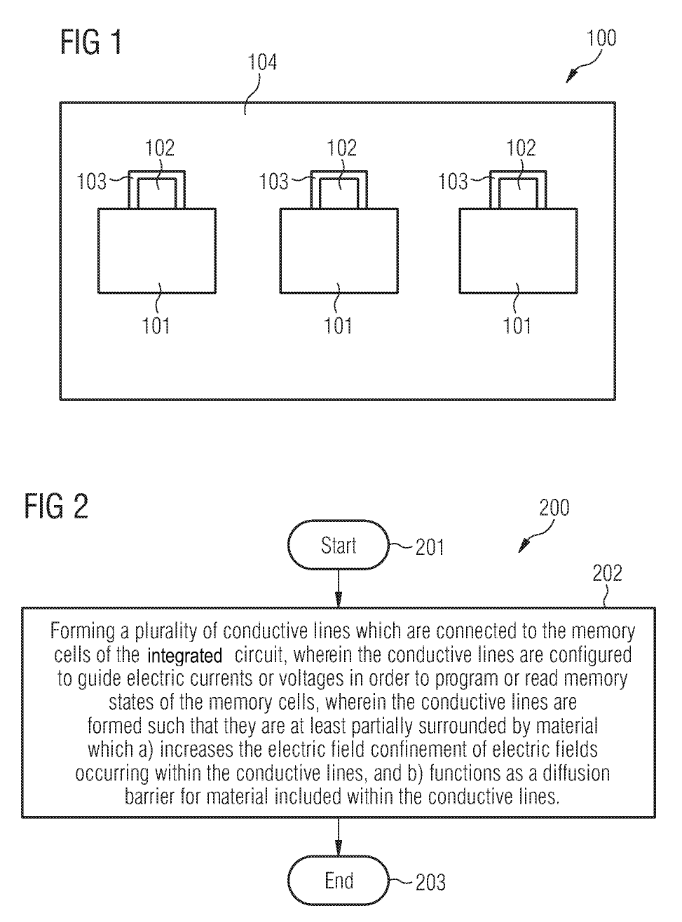

FIG. 1 shows an integrated circuit 100 according to one embodiment of the present invention. The integrated circuit 100 includes a plurality of memory cells 101 and a plurality of conductive lines 102 connected to the memory cells 101. The conductive lines 102 are configured to guide electric currents or voltages in order to program or read memory states of the memory cells 101. The conductive lines 102 are partially surrounded by material 103 which a) increases the electric field confinement of electric fields occurring within the conductive lines 102, and b) functions as a diffusion barrier for material included within the conductive lines 102.

Since the material 103 both increases the electric field confinement and functions as a diffusion barrier, additional material layers having electric field confinement properties or diffusion barrier properties can be omitted. In this way, the manufacturing process of the integrated circuit 100 is simplified.

According to one embodiment of the present invention, the material 103 surrounding the conductive lines 102 includes or consists of ferromagnetic material.

According to one embodiment of the present invention, the material 103 surrounding the conductive lines 102 includes or consists of cobalt (Co).

According to one embodiment of the present invention, the material 103 surrounding the conductive lines 102 includes or consists of a cobalt (Co) alloy.

According to one embodiment of the present invention, the conductive lines 102 include or consist of copper (Cu).

According to one embodiment of the present invention, the material 103 surrounding the conductive lines 102 is embedded into isolation material 104 including or consisting of SiO₂, FeN, or a low-k dielectric material.

According to one embodiment of the present invention, the conductive lines 102 are bit lines or word lines.

It has to be mentioned that for sake of simplicity only some conductive lines are shown in FIG. 1. Of course, additional conductive lines may be provided which contact the memory cells 101 (for example additional conductive lines 102 may contact the memory cells 101 from below).

According to one embodiment of the present invention, the material 103 surrounding the conductive lines 102 has the shape of layers, each layer having a thickness ranging between about 1 nm and about 30 nm. According to one embodiment of the present invention, each layer has a thickness of about 10 nm (this embodiment shows good results). According to one embodiment of the present invention, the integrated circuit is a circuit including magneto-resistive memory cells. However, the embodiments of the present invention may also be applied to integrated circuits including other types of memory cells like phase changing memory devices (e.g., PCRAM devices), programmable metallization memory devices (e.g., CBRAM devices), transition metal oxide (TMO) devices, carbon memory devices, and the like. Further, the embodiments of the present invention are also applicable to integrated circuits which are not memory devices. In particular, the embodiments of present invention are applicable to integrated circuits having copper interconnect areas, i.e., areas having conductive copper lines.

Therefore, more generally, according to one embodiment of the present invention, an integrated circuit comprising a plurality of conductive lines is provided, wherein the conductive lines are configured to guide electric currents or voltages, wherein the conductive lines are at least partially surrounded by material, which a) increases the electric field confinement of electric fields occurring within the conductive lines, and b) functions as a diffusion barrier for material included within the conductive lines.

According to one embodiment of the present invention, a memory device including a plurality of memory cells and a plurality of conductive lines connected to the memory cells is provided. The conductive lines include or consist of copper (Cu). The conductive lines are configured to guide electric currents or voltages in order to program or read memory states of the memory cells. The conductive lines are at least partially surrounded by material including or consisting of cobalt (Co).

FIG. 2 shows a method 200 of manufacturing an integrated circuit including a plurality of memory cells according to one embodiment of the present invention. At 201, the method 200 is started. At 202, several conductive lines are formed which are connected to the memory cells of the integrated circuit. The conductive lines are configured to guide electric currents or voltages in order to program or read memory states of the memory cells. The conductive lines are formed such that they are at least partially surrounded by material which a) increases the electric field confinement of electric fields occurring within the conductive lines, and b) functions as a diffusion barrier for material included within the conductive lines. At 203, the method 200 is terminated.

According to one embodiment of the present invention, at least some of the conductive lines are formed at 202 using the following processes: patterning an isolation layer by forming a trench structure within the isolation layer; depositing a layer of material having electric field confinement properties and diffusion barrier properties on the surface of the trench structure; filling at least a part of remaining space within the trench structure with conductive material. These processes may for example be used for forming conductive lines which are located below the memory cells.

According to one embodiment of the present invention, the following processes may be carried out in order to deposit the layer of material having electric field confinement properties and diffusion barrier properties on the surface of the trench structure: a layer of material having electric field confinement properties and diffusion barrier properties is deposited on the entire top surface of the patterned isolation layer; and a planarization process is carried out until the layer of material having electric field confinement properties and diffusion barrier properties has been removed from parts of the top surface of the patterned isolation layer which are located outside the trench structure. The planarization process may, for example, be a chemical mechanical polishing (CMP) process.

According to one embodiment of the present invention, at least some of the conductive lines are formed using the following processes: a trench structure is formed within an isolation layer; the trench structure is at least partially filled with conductive material; the isolation layer is removed; a layer of material having electric field confinement properties and diffusion barrier properties is deposited on the exposed conductive material. These processes may, for example be carried out in order to form conductive lines which are located above the memory cells.

All embodiments discussed in conjunction with the integrated circuit according to the present invention may also be applied to the embodiments of the method according to the present invention.

According to one embodiment of the present invention, a memory module including at least one integrated circuit according to one embodiment of the present invention is provided. According to one embodiment of the present invention, the memory module is stackable.

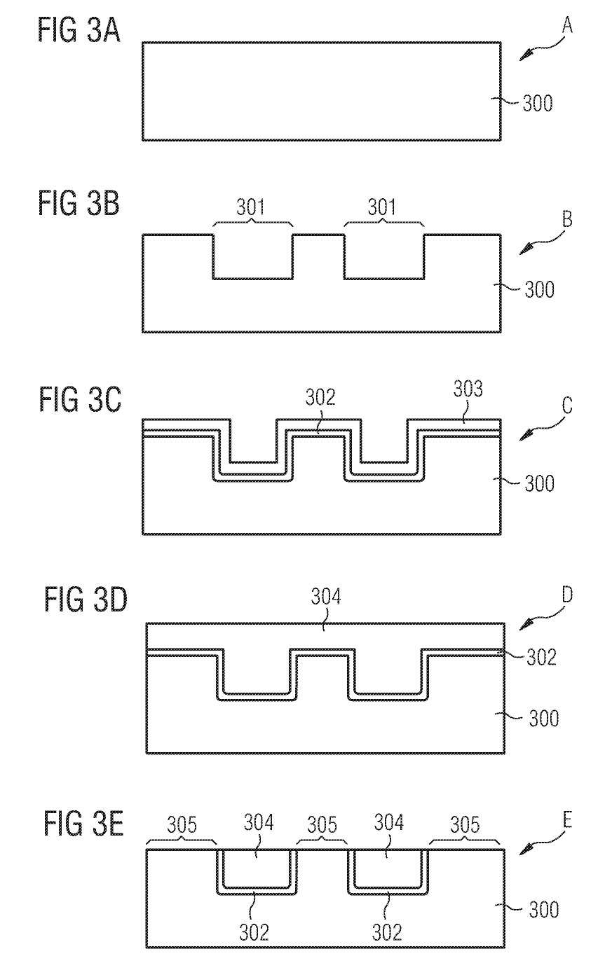

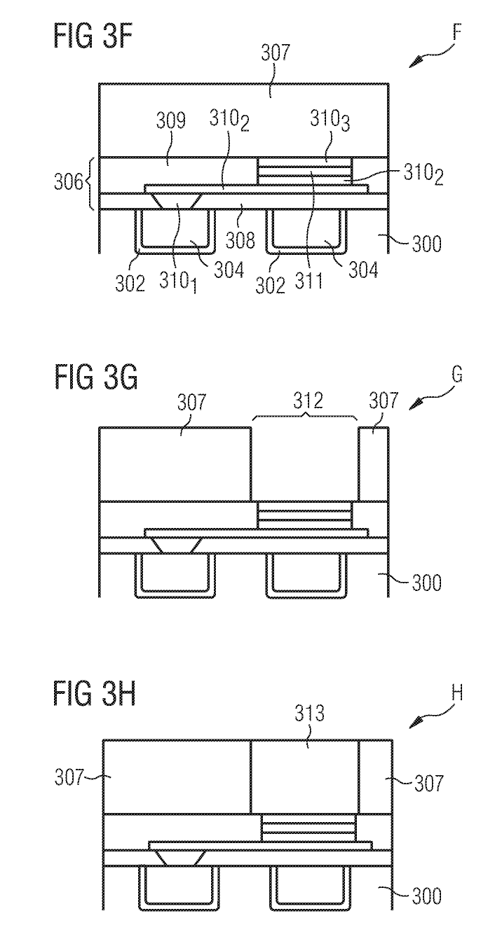

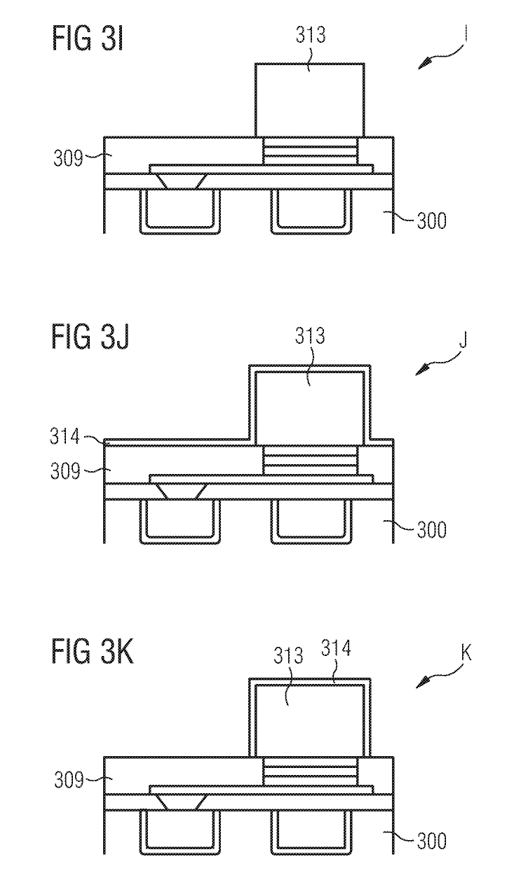

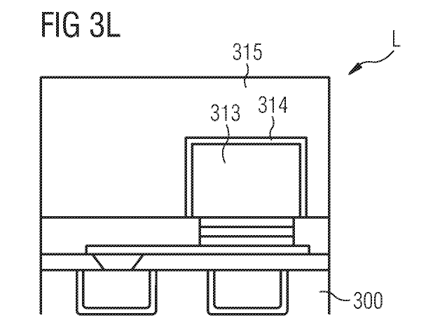

In the following description, making reference to FIGS. 3A to 3L, a method of fabricating an integrated circuit according to one embodiment of the present invention will be explained.

FIG. 3A shows a processing stage A of the method in which an isolation layer 300 is provided which may, for example, include or consist of SiO₂, SiN, or a low-k dielectric material.

FIG. 3B shows a processing stage B of the method in which a trench structure 301 has been formed within the isolation layer 300 using, for example, an etching process. As will become apparent later, the trench structure 301 may, for example, be used to form damascene metal lines.

FIG. 3C shows a processing stage C of the method in which a cobalt layer 302 (a layer including or consisting of cobalt or of a cobalt based alloy) has been deposited on the entire top surface 303 of the patterned isolation layer 300, i.e., the cobalt layer 302 also covers the surface of the trench structure 301 (the sidewall surface and the bottom surface of the trench structure 301). The cobalt layer 302 is used to increase the electric field confinement of electric fields occurring within conductive lines to be formed within the trench structure 301. Further, the cobalt layer 302 functions as a diffusion barrier for material included within the conductive lines to be formed within the trench structure 301, for example, the conductive material. In addition, the cobalt layer 302 may function as a seed layer for growing the conductive material of the conductive lines to be formed within the trench structure 301. The cobalt layer 302 may, for example, deposited using a physical vapor deposition process (PVD process). Then, a copper seed layer 303 is deposited on the cobalt layer 302. The deposition of the copper seed layer 303 may, for example, be carried out “in situ”, i.e. without breaking the vacuum used for depositing the cobalt layer 302.

FIG. 3D shows a processing stage D of the method in which the trench structure 301 has been filled with conductive material 304 (here it is assumed that the conductive material 304 is copper; however, the present invention is not restricted to this material; the material of the seed layer 303 should be adapted to the material of the conductive material 304).

FIG. 3E shows a processing stage E of the method obtained after having carried out a planarization process of the top surface of the structure shown in FIG. 3D. The planarization process is carried out until the cobalt layer 302 has been removed within parts 305 of the top surface of the structure located outside the trench structure 301. The planarization process may, for example, be a chemical mechanical polishing (CMP) process.

FIG. 3F shows a processing stage F obtained after having provided a memory module layer 306 including a plurality of memory cells (at least one memory cell) on the structure obtained in the processing stage shown in FIG. 3E. Further, an isolation layer 307 has been provided on the memory cell layer 306. The memory cell layer 306 includes a first isolation layer 308, a second isolation layer 309, conductive elements 310₁, 310₂, and 310₃ and active material elements 311. The isolation layer 307 is also known as magnetic tunneling interlayer dielectric (MT ILD). The isolation layer 309 is also known as magnetic tunneling junction interlayer dielectric (MTJ ILD). The active material elements 311 usually respectively comprise a plurality of layers like a pinning layer, a tunneling barrier layer, and a free layer, or even more layers.

FIG. 3G shows a processing stage G obtained after having formed a trench structure 312 within the isolation layer 307. The trench structure 312 is positioned such that its bottom surface coincides with the top surface of the conductive element 310₃. The formation of the trench structure 312 may, for example, be carried out using an etching process. Possible examples of material combinations MTJ ILD/MT ILD are SiN/SiO₂, SiO₂/SiN, SiC/SiO₂, or SiCN/SiO₂.

FIG. 3H shows a processing stage H of the method obtained after having filled the trench structure 312 with conductive material 313, for example copper. An additional planarization process of the top surface of the thus obtained structure may be carried out (using, for example, a CMP process).

FIG. 3I shows a processing stage I obtained after having removed the isolation layer 307, thereby exposing the conductive material 313. The removal of the isolation layer 307 may for example be carried out using a wet etching or dry etching process or diluted hydrogen fluorine (HF). In order to avoid a removal of the isolation layer 309, an etching material may be used which is not capable of etching the material of the isolation layer 309 (“selective etching process”).

FIG. 3J shows a processing stage J obtained after having deposited a cobalt layer (a layer which includes or consists of cobalt or includes or consists of a cobalt based alloy) 314 on the top surface of the structure shown in FIG. 3I, i.e. which covers the top surface of the isolation layer 309 and the surface of the conductive material 313. The cobalt layer 314 may, for example, be deposited using a PVD process.

FIG. 3K shows a processing stage K in which the cobalt layer 314 has been removed from the top surface of the isolation layer 309, i.e. the cobalt layer 314 only remains on the surface of the conductive material 313. The processing stages J and K may also be replaced by depositing the cobalt layer 314 only on the top surface of the conductive material 313, for example, by masking the top surface of the isolation layer 309. The removal of the cobalt layer 314 from the top surface of the isolation layer 309 may, for example, be carried out using a lithography process in conjunction with an “inverted MT image”, i.e., the conductive material 313 is formed before the formation of the isolation layer 315 embedding the conductive material 313, and not vice versa.

FIG. 3L shows a processing stage L obtained after having deposited an isolation layer 315 covering the top surface of the isolation layer 309 and the top surface of the cobalt layer 314. A final CMP process may be carried out in order to planarize the top surface of the isolation layer 315.

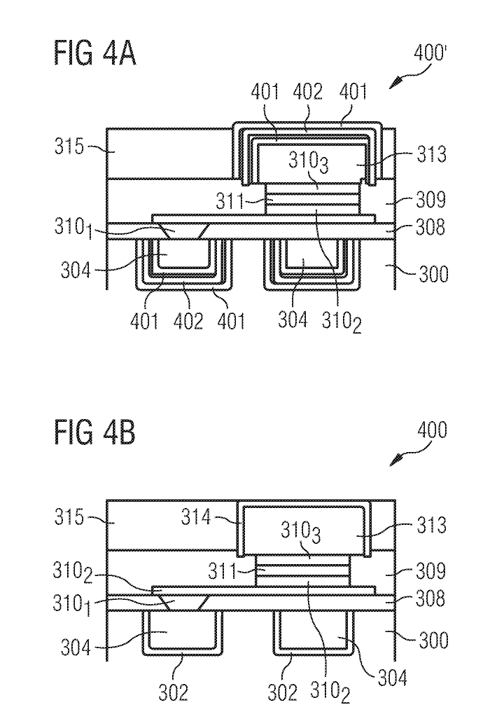

Thus, an integrated circuit shown in FIG. 4b is obtained. In contrast, FIG. 4a shows an integrated circuit 400′ in which, instead of one single cobalt layer 314, two different layers are used to surround the conductive material 313 and the conductive material 304, namely a diffusion barrier layer 401 which may include Ta, TaN, or Ta/TaN, for example, and a field confinement layer (“ferromagnetic liner”) 402 which is surrounded by the diffusion barrier 401. Compared to the integrated circuit 400 shown in FIG. 4b, the integrated circuit 400′ of FIG. 4a requires more space and is more complicated to manufacture.

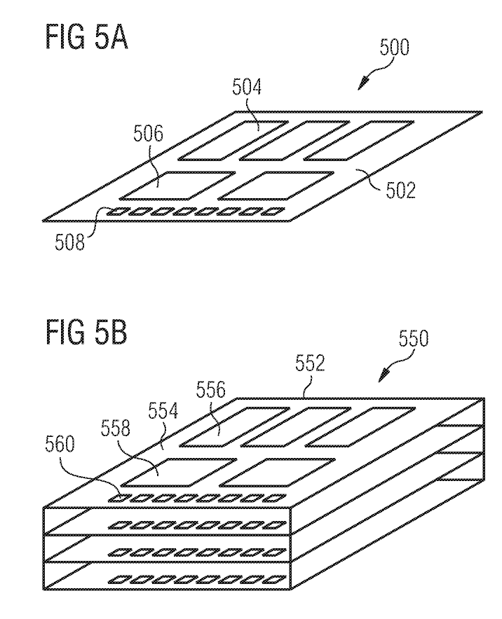

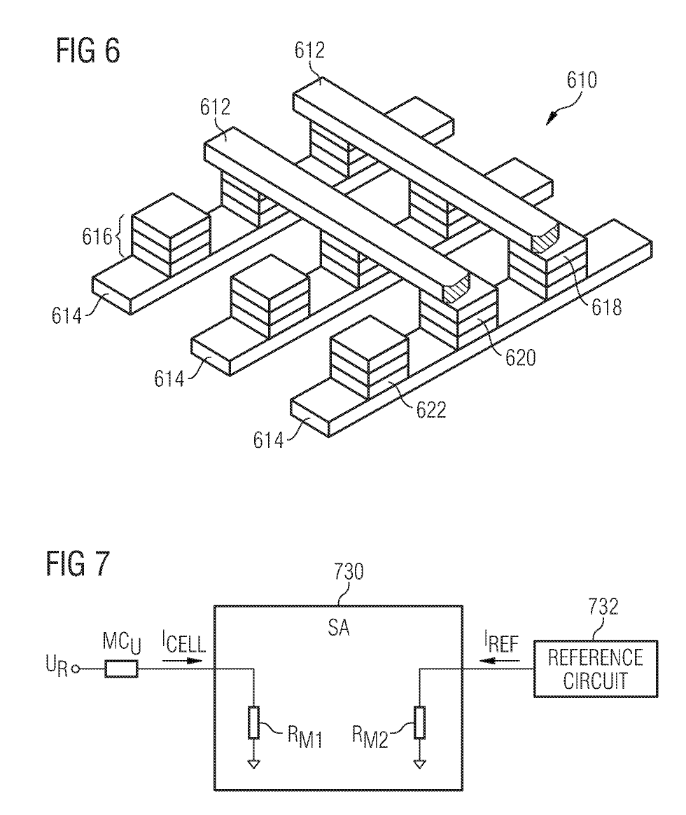

As shown in FIGS. 5A and 5B, in some embodiments, integrated circuits/memory devices such as those described herein may be used in modules. In FIG. 5A, a memory module 500 is shown, on which one or more integrated circuits/memory devices 504 are arranged on a substrate 502. The integrated circuits/memory devices 504 include numerous memory cells. The memory module 500 may also include one or more electronic devices 506, which may include memory, processing circuitry, control circuitry, addressing circuitry, bus interconnection circuitry, or other circuitry or electronic devices that may be combined on a module with integrated circuits/memory devices, such as the integrated circuits/memory devices 504. Additionally, the memory module 500 includes multiple electrical connections 508, which may be used to connect the memory module 500 to other electronic components, including other modules.

As shown in FIG. 5B, in some embodiments, these modules may be stackable, to form a stack 550. For example, a stackable memory module 552 may contain one or more integrated circuits/memory devices 556, arranged on a stackable substrate 554. The integrated circuits/memory devices 556 contains memory cells. The stackable memory module 552 may also include one or more electronic devices 558, which may include memory, processing circuitry, control circuitry, addressing circuitry, bus interconnection circuitry, or other circuitry or electronic devices that may be combined on a module with integrated circuits/memory devices, such as the integrated circuits/memory devices 556. Electrical connections 560 are used to connect the stackable memory module 552 with other modules in the stack 550, or with other electronic devices. Other modules in the stack 550 may include additional stackable memory modules, similar to the stackable memory module 552 described above, or other types of stackable modules, such as stackable processing modules, control modules, communication modules, or other modules containing electronic components.

In the following description, further aspects of the present invention will be explained.

Thermal Select MRAM requires at least one highly conductive metal line to generate magnetic fields for switching operation. Copper lines have a lower resistivity, compared to tungsten lines or aluminum lines. Adding of ferromagnetic liners (FML) (e.g. a high permeability layer) can double the field confinement.

In this approach, the copper lines are combined with diffusion barriers such as Ta or TaN or Ta/TaN. The adding of FMLs increases the thickness of higher resistive layers, consuming space for copper metal lines.

According to one embodiment of the present invention, cobalt or a cobalt alloy is used to embody the Cu diffusion layer and the FML, hence there is no additional space consumption, resulting higher conductivity at the given feature size. This is possible due to the property of cobalt or a cobalt alloy: From the phase diagram it can be derived that there is no intermetallic compound in the Co/Cu binary systems. This binary system has negligible mutual solubility, hence provides very good diffusion barrier properties. Cobalt has also a high permeability that can fulfill field confinement requirements.

Within the scope of the present invention, the terms “connected” and “coupled” may both mean direct and indirect connecting/coupling.

While the invention has been particularly shown and described with reference to specific embodiments, it should be understood by those skilled in the art that various changes in form and detail may be made therein without departing from the spirit and scope of the invention as defined by the appended claims. The scope of the invention is thus indicated by the appended claims and all changes, which come within the meaning and range of equivalency of the claims, are therefore intended to be embraced.

What is claimed is:

1. An integrated circuit comprising:
a plurality of memory cells; and
a plurality of conductive lines coupled to the memory cells;
wherein the conductive lines are configured to guide electric currents or voltages in order to program or read memory states of the memory cells,
wherein the conductive lines are at least partially surrounded by material that increases electric field confinement of electric fields occurring within the conductive lines, and functions as a diffusion barrier for material included within the conductive lines.

2. The integrated circuit according to claim 1, wherein the material surrounding the conductive lines comprises ferromagnetic material.

3. The integrated circuit according to claim 1, wherein the material surrounding the conductive lines comprises Co.

4. The integrated circuit according to claim 3, wherein the material surrounding the conductive lines comprises a Co alloy.

5. The integrated circuit according to claim 1, wherein the conductive lines comprise Cu.

6. The integrated circuit according to claim 1, wherein the material surrounding the conductive lines is embedded into isolation material comprising SiO₂, SiN, or a low k dielectric material.

7. The integrated circuit according to claim 1, wherein the conductive lines are bit lines or word lines.

8. The integrated circuit according to claim 1, wherein the material surrounding the conductive lines forms a layer having a thickness ranging between 1 nm and 30 nm.

9. The integrated circuit according to claim 1, wherein the memory cells are magneto-resistive memory cells.

10. A memory device comprising:
a plurality of memory cells; and
a plurality of conductive lines coupled to the memory cells, the conductive lines comprising Cu,
wherein the conductive lines are configured to guide electric currents or voltages in order to program or read memory states of the memory cells,
wherein the conductive lines are at least partially surrounded by material comprising Co.

11. A method of manufacturing an integrated circuit comprising a plurality of memory cells, the method comprising:
forming a plurality of conductive lines which are coupled to the memory cells, wherein the conductive lines are configured to guide electric currents or voltages in order to program or read memory states of the memory cells,
wherein the conductive lines are formed such that they are at least partially surrounded by material that increases electric field confinement of electric fields occurring within the conductive lines, and functions as a diffusion barrier for material included within the conductive lines.

12. The method according to claim 11, wherein at least some of the conductive lines are formed using the following processes:
patterning an isolation layer by forming a trench structure within the isolation layer;
depositing a layer of material having electric field confinement properties and diffusion barrier properties on a surface of the trench structure; and
filling at least a part of remaining space within the trench structure with conductive material.

13. The method according to claim 12, wherein, in order to deposit the layer of material having electric field confinement properties and diffusion barrier properties on the surface of the trench structure;
a layer of material having electric field confinement properties and diffusion barrier properties is deposited on an entire top surface of the patterned isolation layer; and
a planarization process is carried out until the layer of material having electric field confinement properties and diffusion barrier properties has been removed from parts of the top surface of the patterned isolation layer, which are located outside the trench structure.

14. The method according to claim 13, wherein a plurality of the memory cells is formed on or above the planarized isolation layer.

15. The method according to claim 11, wherein at least some of the conductive lines are formed using the following processes:
forming a trench structure within an isolation layer;
at least partially filling the trench structure with conductive material;
removing the isolation layer; and
depositing a layer of material having electric field confinement properties and diffusion barrier properties on the exposed conductive material.

16. The method according to claim 15, wherein the isolation layer is formed on or above a layer comprising a plurality of the memory cells.

17. The method according to claim 11, wherein the material surrounding the conductive lines comprises ferromagnetic material.

18. The method according to claim 11, wherein the material surrounding the conductive lines comprises Co.

19. The method according to claim 18, wherein the material surrounding the conductive lines comprises a Co alloy.

20. The method according to claim 11, wherein the conductive material comprises Cu.

21. The method according to claim 11, wherein the material surrounding the conductive lines is embedded into isolation material comprising SiO₂, SiN, or a low k dielectric material.

22. The method according to claim 11, wherein the conductive lines are bit lines or word lines.

23. The method according to claim 11, wherein the integrated circuit is a magneto-resistive circuit.

24. A method of manufacturing a memory device comprising a plurality of memory cells, the method comprising:
forming a plurality of conductive lines connected to the memory cells, the conductive lines comprising Cu and being configured to guide electric currents or voltages in order to program or read memory states of the memory cells,
wherein the conductive lines are formed such that they are at least partially surrounded by material comprising Co.

25. An integrated circuit comprising a plurality of conductive lines,
wherein the conductive lines are configured to guide electric currents or voltages,
wherein the conductive lines are at least partially surrounded by material which increases the electric field confinement of electric fields occurring within the conductive lines, and functions as a diffusion barrier for material included within the conductive lines.
